(19) United States
(12) Patent Application Publication
(10) Pub. No.: US 2025/0259677 A1
(43) Pub. Date: Aug. 14, 2025

(54) DATA RETENTION OF PARTIALLY PROGRAMMED BLOCKS OF NON-VOLATILE MEMORY DEVICES

(71) Applicant: Microchip Technology Incorporated, Chandler, AZ (US)

(72) Inventors: Pitamber SHUKLA, San Jose, CA (US); Gerhard RISTAU, Coquitlam (CA); Brent DINGSDALE, Delta (CA); Tim James SYMONS, Anmore (CA)

(21) Appl. No.: 18/935,416

(22) Filed: Nov. 1, 2024

Related U.S. Application Data
(60) Provisional application No. 63/552,666, filed on Feb. 12, 2024.

(51) Int. Cl. G11C 14/00

(52) U.S. Cl. CPC G11C 14/0018

(57) ABSTRACT

In some implementations, a controller may detect a power loss event on a non-volatile memory device. The controller may perform, based on detecting the power loss event, a first write operation to write data to a first portion of a block of the non-volatile memory device. Prior to the first write operation, the data may be stored in a memory of a controller of the non-volatile memory device. After the first write operation, the first portion of the block may include programmed wordlines. After the first write operation, a second portion of the block may include unprogrammed wordlines. The controller may perform a second write operation to write padding data to an unprogrammed wordline of the unprogrammed wordlines that is adjacent to a last programmed wordline of the programmed wordlines.

### RELATED APPLICATION

This application claims priority to U.S. Provisional Patent Application No. 63/552,666 entitled “IMPROVING DATA RETENTION OF PARTIALLY PROGRAMMED BLOCKS OF NON-VOLATILE MEMORY DEVICES,” filed Feb. 12, 2024, which is incorporated herein by reference in its entirety.

### FIELD

The present disclosure generally relates to partially programmed blocks of non-volatile memory devices and, for example, to improving data retention of the partially programmed blocks.

### BACKGROUND

A non-volatile memory device may include a memory device that may store and retain data without external power supply. One example of a non-volatile memory device is a NAND flash memory device. In some situations, one or more NAND flash memory devices may be included in a device called a solid-state drive (SSD). The one or more NAND flash memory devices may store data that is used by a host computing device. The SSD may include a controller that controls operations performed on the SSD. The operations may include read operations, write operations, and erase operations.

### SUMMARY

In some implementations, a method comprising: detecting a power loss event on a non-volatile memory device; performing, based on detecting the power loss event, a first write operation to write data to a first portion of a block of the non-volatile memory device, wherein, prior to the first write operation, the data is stored in a memory of a controller of the non-volatile memory device, wherein, after the first write operation, the first portion of the block includes programmed wordlines, and wherein, after the first write operation, a second portion of the block includes unprogrammed wordlines; and performing a second write operation to write padding data to an unprogrammed wordline of the unprogrammed wordlines that is adjacent to a last programmed wordline of the programmed wordlines.

In some implementations, a system comprising: a controller to: perform a first write operation to write data, of the controller, to a first portion of a block of a non-volatile memory device, wherein the first portion of the block includes programmed wordlines, and wherein a second portion of the block includes unprogrammed wordlines; and perform a second write operation to write padding data to an unprogrammed wordline of the unprogrammed wordlines that is adjacent to a last programmed wordline of the programmed wordlines, wherein the last programmed wordline is a last wordline that is written to the first portion by the controller during the first write operation.

In some implementations, a computer program product comprising: one or more computer readable storage media, and program instructions collectively stored on the one or more computer readable storage media, the program instructions comprising: program instructions to perform a first write operation on a first portion of a block of a non-volatile memory device, wherein the first portion of the block includes programmed wordlines, and wherein a second portion of the block includes unprogrammed wordlines; and perform a second write operation to write padding data to an unprogrammed wordline of the unprogrammed wordlines that is adjacent to a last programmed wordline, of the programmed wordlines.

### BRIEF DESCRIPTION OF THE DRAWINGS

FIG. 1 is a diagram of an example implementation described herein.

FIG. 2 is a diagram of an example partially programmed block of a non-volatile memory device with padding data.

FIGS. 3-5 are flowcharts of an example process associated with improving data retention of partially programmed blocks.

### DETAILED DESCRIPTION

The following detailed description of example implementations refers to the accompanying drawings. The same reference numbers in different drawings may identify the same or similar elements.

A system may include a controller, a volatile memory, and one or more non-volatile memory devices (e.g., NAND flash memory devices). The operations may include read operations, write operations, and erase operations that are performed on the one or more non-volatile memory devices. The controller may include the volatile memory and the volatile memory may store data. The volatile memory may include a double data rate (DDR) dynamic random-access memory (DRAM). The one or more non-volatile memory devices may be used to save a copy of data from the volatile memory in the event of a power loss to enable recovery of the data when power is restored. Accordingly, the system may implement persistent backup of data (onto non-volatile memory devices) from a volatile memory (the DRAM) in the event of power loss.

The system may include a solid-state drive (SSD). In some situations, the system may experience a power loss event (e.g., an event during which power on the system is interrupted or suspended). The controller may detect the power loss event. Based on detecting the power loss event, the controller may perform a write operation to write the data (stored by the volatile memory) to a non-volatile memory device (e.g., a persistent non-volatile memory device) of the system. In other words, the controller may cause a backup of the data to be stored on the non-volatile memory device.

Typically, a size of data written to the block is predetermined. An SSD is typically structured into predefined memory blocks (or blocks) that ideally should be written in their entirety with data. A size of data copied from the volatile memory may not be the same size as a size of a block, which results in the block being partially written (e.g., results in a partially written block). For example, the size of the data may be up to 16 mebibytes (MiB), which may be less than a storage capacity of the block. In other words, the size of the data may be typically less than the storage capacity of the block. Accordingly, as a result of the write operation, the block may be partially written. In other words, as a result of the write operation, a portion of the block may be programmed while another portion of the block may remain unprogrammed. In this regard, the block may be referred to as a partially programmed block that includes a programmed portion and an unprogrammed portion.

The partially programmed block may be subject to multiple issues due to the structure and architecture of a non-volatile memory (e.g., multiple technical problems). For example, the partially programmed block may be subject to poor data reliability and to read latency. With respect to the poor data reliability, a last programmed wordline (e.g., a last written wordline) of the programmed portion may subject to more data retention loss. For example, because the last programmed wordline is adjacent to one or more unprogrammed wordlines of the unprogrammed portion, electrons from the last programmed wordline may migrate toward the one or more unprogrammed wordlines. Accordingly, the migration of electrons may enhance the data retention degradation of the last programmed wordline. Therefore, the last programmed wordline being adjacent to the one or more unprogrammed wordlines may lead to poor data reliability and poor data integrity of the last programmed wordline.

With respect to read latency, the one or more unprogrammed wordlines (adjacent to the last written wordline) may be in an erased state. In some situations, other unprogrammed wordlines of the unprogrammed portion may be in an erased state. The unprogrammed wordlines being in the erased state may impact a threshold voltage of the last programmed wordline. For example, the threshold voltage of the last programmed wordline may appear lower than the threshold voltage of other programmed wordlines of the programmed portion. The difference between the threshold voltages (of the last programmed wordline and the other programmed wordlines) may cause read latency when performing a read operation to read data stored by the last programmed wordline. For example, the difference between the threshold voltages may cause read errors when read operations are performed on the last programmed wordline. Operations may be performed to correct the read errors. The operations may consume time and may cause delays regarding the read operations.

Implementations described herein provide a technical solution to the technical problems discussed above. For example, implementations described herein are directed to performing a write operation of random data (e.g., referred to as “padding data”) on an unprogrammed portion of a block (of a non-volatile memory device that has been partially programmed) to rebalance the block programmed state and to prevent a wordline of a programmed portion of the block from being subject to read latency issues and data retention issues. For example, implementations described herein are directed to performing a write operation to write padding data to one or more unprogrammed wordlines (of the unprogrammed portion) that are adjacent to a last programmed wordline of the programmed portion. The non-volatile memory device may include a NAND flash memory device.

The padding data may also be referred to as dummy data. The programmed portion may include programmed wordlines and the unprogrammed portion may include unprogrammed wordlines. The last programmed wordline may be a last written wordline of the programmed portion.

In some situations, a controller may perform the write operation after detecting a power loss event on an SSD that includes the controller and the non-volatile memory device. For example, based on detecting the power loss event, the controller may write data stored by a volatile memory of the controller to the non-volatile memory device (e.g., data loss of the data stored on the volatile memory). Because of a limitation regarding the amount of data stored by the memory of the controller, the block may be partially programmed after writing the data to the block. In other words, a portion of the block may be unprogrammed.

To reduce or prevent issues (e.g., read latency issues, data retention issues, and other reliability issues) that occur as a result of partially programming the block, the controller may write padding data to the one or more unprogrammed wordlines that are adjacent to the last programmed wordline. In some implementations, the padding data may include a set of bits that matches bits stored by the last programmed wordline. In some examples, an entirety of the bits stored by the last programmed wordline may be included in the set of bits. In some examples, a portion of the bits stored by the last programmed wordline may be included in the set of bits. In some examples, the portion of the bits may be predetermined by the controller. In some examples, the portion of the bits may be randomly selected by the controller. In some examples, the controller may determine the padding data (e.g., a pattern of the padding data) by taking into consideration overage associated with operations performed on the memory device and/or associated with power consumption of the memory device. In some examples, the padding data may be an SLC random pattern (e.g., random data programmed using one bit per cell). In this regard, if the block is partially programmed using SLC programming (e.g., programming using one bit per cell), then the padding data may be the SLC data pattern. In some examples, the padding data may be a TLC random pattern (e.g., random data programmed using three bits per cell). In this regard, if the block is partially programmed using TLC programming (e.g., programming using three bit per cell), then the padding data may be the TLC data pattern. In some examples, the padding data may be a QLC random pattern (e.g., random data programmed using four bits per cell). In this regard, if the block is partially programmed using QLC programming (e.g., programming using four bit per cell), then the padding data may be the QLC data pattern. In some examples, the padding data may be a solid level random pattern. In some situations, solid level data pattern (and data pattern same as data written to the last written wordline of the block) may provide an improvement, over the aforementioned data patterns, with respect to improving a reliability of the last written wordline as well as with respect to reducing a read latency concern on the last written wordline.

Overall, the controller may determine a pattern for the data padding by considering a programming power usage overhead. For example, determining a pattern for the padding data may involve use of additional data (e.g., additional with respect to existing user data). In this regard, the padding data may be determined by allocating resources for overhead time and/or by allocating power for determining a pattern for the padding data in the event of a power loss condition on the storage device.

In some implementations, the padding data may include a pattern of bits that matches a pattern of bits stored by the last programmed wordline. In some examples, the pattern of bits (of the padding data) may match an entirety of the pattern of bits stored by the last programmed wordline. In some examples, the pattern of bits (of the padding data) may match a portion of the pattern of bits stored by the last programmed wordline. In some examples, the portion of the pattern of bits (of the padding data) may be predetermined by the controller. In some examples, the portion of the pattern of bits (of the padding data) may be randomly selected by the controller.

In some implementations, the padding data may include random data. In some implementations, the padding data may include predetermined data. The padding data may reduce a migration of electrons from the last programmed wordline toward the one or more unprogrammed wordlines. By reducing the migration of electrons, the last programmed wordline will be subject to reduced data retention degradation. In some implementations, the padding data may be written to a set of unprogrammed wordlines that includes the one or more unprogrammed wordlines that are adjacent to the last programmed wordline. In some examples, the same pattern of bits may be written to the one or more unprogrammed wordlines. In some examples, different patterns of bits may be written to the one or more unprogrammed wordlines.

By writing the padding data as described herein, the controller may reduce or prevent read latency issues and data retention issues that occur as a result of partially programming a block of a non-volatile memory device. Accordingly, the controller may provide a technical solution to the technical problems described herein.

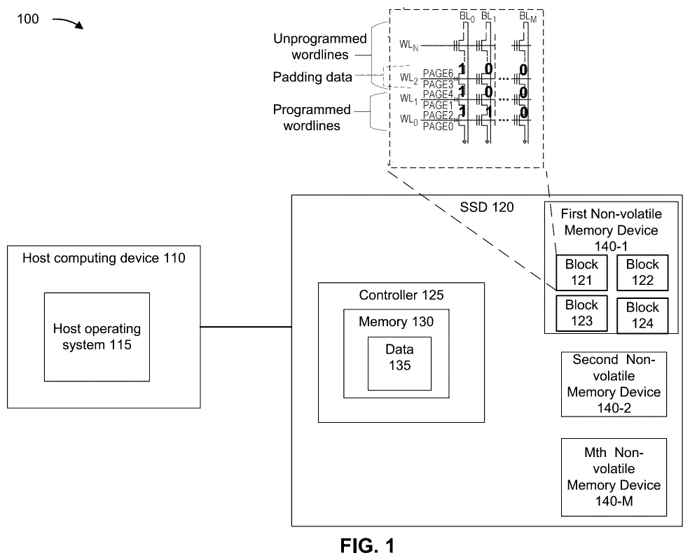

FIG. 1 is a diagram of an example implementation 100 described herein. As shown in FIG. 1, example implementation 100 includes a host computing device 110 and an SSD 120. Host computing device 110 may include one or more devices adapted to receive, generate, store, process, and/or provide information associated with improving data retention on a partially programmed block. Host computing device 110 may include a communication device and a computing device. For example, host computing device 110 may include a wireless communication device, a mobile phone, a user equipment, a laptop computer, a tablet computer, a desktop computer, or a similar type of device. As shown in FIG. 1, host computing device 110 may include a host operating system 115.

As shown in FIG. 1, SSD 120 may include a controller 125. As an example, controller 125 may include an application-specific integrated circuit (ASIC). Alternatively, controller 125 may include firmware. As shown in FIG. 1, controller 125 may include memory 130. In some examples, controller 125 may include a controller that performs operations using firmware stored on memory 130.

As an example, memory 130 may include a random-access memory (RAM), such as a static RAM (SRAM) or dynamic random-access memory (DRAM). For instance, memory 130 may include a double data rate (DDR) DRAM. In some instances, memory 130 may store data. The data may be used by controller 125 to perform one or more operations on SSD 120 (or to cause one or more operations to be performed on SSD 120). In some examples, the data may include data received from host computing device 110, a logical to physical (L2P) table, data regarding program/erase cycles for different blocks and/or wordlines, and/or data regarding garbage collection.

As shown in FIG. 1, SSD 120 may include a first non-volatile memory device 140-1, a second non-volatile memory device 140-2, up to an mth non-volatile memory device 140-M (collectively “non-volatile memory devices 140” and individually “non-volatile memory device 140”). A non-volatile memory device 140 may store data provided by host computing device 110. In some examples, a non-volatile memory device 140 may include a NAND flash memory device.

A non-volatile memory device 140 may include a single level cell (SLC) non-volatile memory device (e.g., a non-volatile memory device with SLC cells), a triple level cell (TLC) non-volatile memory device (e.g., a non-volatile memory device with TLC cells), a quad level cell (QLC) non-volatile memory device (e.g., a non-volatile memory device with QLC cells), or a multi level cell (MLC) non-volatile memory device (e.g., a non-volatile memory device with MLC cells), without limitation. While examples herein may be described with respect to NAND flash memory device, implementations described herein may be applicable to other types of non-volatile memory devices, such as ferroelectric random-access memory (FeRAM), magnetic random-access memory (MRAM), phase-change memory (PCM), or NOR flash memory devices, among other examples.

As shown in FIG. 1, for example, first non-volatile memory device 140-1 may include a first block 121, a second block 122, and so on. As shown in FIG. 1, for example, first block 121-1 may include multiple wordlines (e.g., WL₀, WL₁, and so on) and may include multiple bitlines (e.g., BL₀, BL₁, and so on).

As explained herein, in some situations, upon a power loss event on SSD 120, controller 125 may write the data (stored by memory 130) to a block of a non-volatile memory device 140. The data may be obtained from memory 130 and may be used by controller 125 to perform one or more operations on SSD 120 (or to cause one or more operations to be performed on SSD 120). In some examples, the data may include data received from host computing device 110, a logical to physical (L2P) table, data regarding program/erase cycles for different blocks and/or wordlines, and/or data regarding garbage collection. As an example, controller 125 may write the data to first block 121 of first non-volatile memory device 140-1.

Because of a size of the data is less than a storage capacity of first block 121, first block 121 may be a partially programmed block as a result of writing the data to first block 121. As shown in FIG. 1, first block 121 may include programmed wordlines and unprogrammed wordlines. In an effort to prevent or mitigate the issues associated with partially programmed blocks as described herein, controller 125 may write padding data to first block 121, as described herein. For example, controller 125 may write padding data to reduce read latency and to reduce data retention degradation. As shown in FIG. 1, for example, padding data may be written to one or more unprogrammed wordlines of the unprogrammed wordlines that are adjacent to a last programmed wordline of the programmed wordlines. In some situations, the padding data may be written as part of a data backup operation regarding the data to first block 121. In this regard, the one or more unprogrammed wordlines may not exceed a number threshold of unprogrammed wordlines to prevent burdening the data backup operation.

While examples herein may be described with respect to SLC non-volatile memory devices (1 bit per cell), implementations described herein may be applicable to other types of non-volatile memory devices, such as MLC non-volatile memory devices (2 bits per cell), TLC non-volatile memory devices (3 bits per cell), QLC non-volatile memory devices (4 bits per cell), and MLC non-volatile memory devices (2 bits per cell), without limitation.

As indicated above, FIG. 1 is provided as an example. Other examples may differ from what is described with regard to FIG. 1. The number and arrangement of devices shown in FIG. 1 is provided as an example. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) shown in FIG. 1 may perform one or more functions described as being performed by another set of devices shown in FIG. 1.

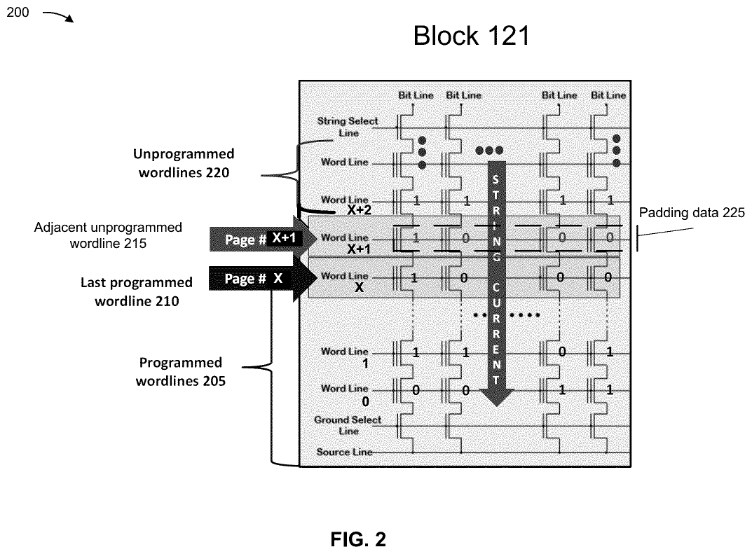

FIG. 2 is a diagram of an example partially programmed block 200 of a non-volatile memory device with padding data. While examples herein may be described with respect to SLC non-volatile memory devices (1 bit per cell), implementations described herein may be applicable to other types of non-volatile memory devices, MLC non-volatile memory devices (2 bits per cell), TLC non-volatile memory devices (3 bits per cell), and QLC non-volatile memory devices (4 bits per cell), without limitation. In some situations, example partially programmed block 200 may include block 121 of first non-volatile memory device 140-1. In some examples, block 121 may be partially programmed as a result of controller 125 copying data from memory 130 to block 121 (e.g., as part of a data backup operation regarding the data). Block 121 may be partially programmed because a size of the data that is copied from memory 130 to block 121 does not exceed a storage capacity of block 121.

As shown in FIG. 2, block 121 may include programmed wordlines 205 and unprogrammed wordlines 220. Programmed wordlines 205 may include wordline 0 to wordline X. Unprogrammed wordlines 220 may include wordline X+1, wordline X+2, and so on. As shown in FIG. 2, unprogrammed wordlines 220 may be in an erase state (e.g., “1” may written to cells of unprogrammed wordlines 220). As shown in FIG. 2, padding data may be written to wordline X+1 (e.g., as part of the data backup operation).

In some examples, when copying the data from memory 130 to block 121, controller 125 may write the data to wordlines of block 121 in a sequential manner. For example, controller 125 may write a first portion of the data to wordline 0, followed by a second portion of the data to wordline 1, and so on. Wordline X may be a last programmed wordline 210 of programmed wordlines 205. Wordline X+1 may be an adjacent unprogrammed wordline 215 (i.e., an unprogrammed wordline adjacent to the last programmed wordline 210).

Before writing padding data 225 to wordline X+1, a threshold voltage (for reading data written to wordline X) may be different compared to wordline 1 because of the string current mismatch during the read operation. String current on wordline X (without padding data on wordline X+1) may be higher during a read operation compared to wordline 1. As used herein, “string current” may refer to a current flow through a bit line/string during an operation on the non-volatile memory device (e.g., a read operation). For example, during a read operation, a bit line/string may be pre-charged to a predetermined voltage level. Subsequently, a pass voltage may be applied to all cell other than a cell that is to be read during the read operation. An appropriate read voltage (e.g., exceeding a threshold voltage of the cell to be read) may be applied to the cell for which written data is to be read (e.g., is to be determined). Subsequently, a current may flow through the bit line/string. The current flowing through the bit line may be referred to as the string current. In this regard, before writing padding data 225 to wordline X+1, wordline X may not be surrounded by (or included between) programmed wordlines. For example, a neighbor wordline of wordline X may be an unprogrammed wordline (e.g., wordline X+1). Conversely, wordline 1 may be surrounded by (or included between) programmed wordlines. For example, wordline 1 may be provided between neighbor wordlines that are programmed wordlines (e.g., wordlines 0 and 2).

The difference in threshold voltages between programmed wordlines (e.g., wordline 1 and wordline X) may cause read latency issues, as described herein. Additionally, because last programmed wordline 210 has a neighboring wordline in an erase state (e.g., adjacent unprogrammed wordline 215), last programmed wordline 210 may experience a vertical data retention degradation.

To avoid the issues mentioned above, padding data 225 may be written to one or more unprogrammed wordlines that are adjacent to last programmed wordline 210 (e.g., wordline X+1, wordline 514, without limitation). Padding data 225 may be written after writing the data to programmed wordlines 205. For example, padding data may include a data pattern of data written to last programmed wordline 210. In some examples, padding data may include a random data pattern.

By writing padding data 225 as described herein, controller 125 may reduce or prevent read latency issues and data retention issues that occur as a result of partially programming block 121. As indicated above, FIG. 2 is provided as an example. Other examples may differ from what is described with regard to FIG. 2.

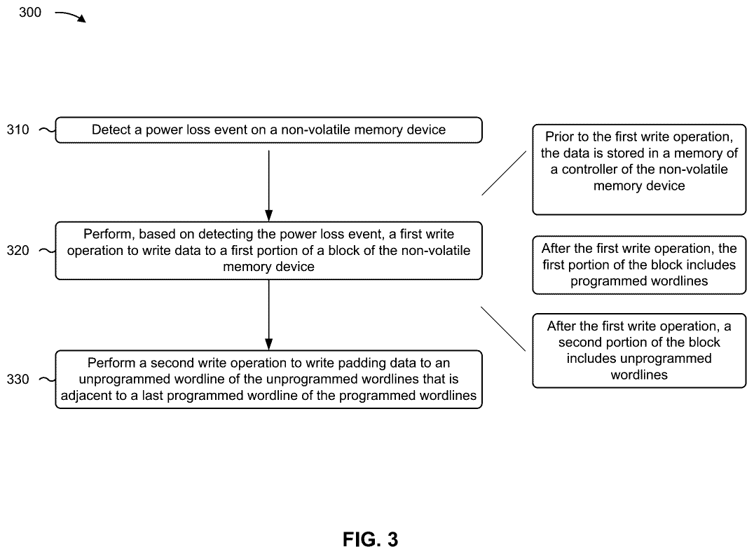

FIG. 3 is a flowchart of an example process 300 associated with improving data retention of partially programmed blocks of non-volatile memory devices field brief description of the drawings. In some implementations, one or more process blocks of FIG. 3 may be performed by a controller (e.g., controller 125). In some implementations, one or more process blocks of FIG. 3 may be performed by another device or a group of devices separate from or including the controller, such as a non-volatile memory device (e.g., non-volatile memory device 140).

As shown in FIG. 3, process 300 may include detecting a power loss event on a non-volatile memory device (block 310). For example, the controller may detect a power loss event on a non-volatile memory device, as described above.

As further shown in FIG. 3, process 300 may include performing, based on detecting the power loss event, a first write operation to write data to a first portion of a block of the non-volatile memory device (block 320). For example, the controller may perform, based on detecting the power loss event, a first write operation to write data to a first portion of a block of the non-volatile memory device. Prior to the first write operation, the data may be stored in a memory of a controller of the non-volatile memory device. After the first write operation, the first portion of the block may include programmed wordlines. After the first write operation, a second portion of the block may include unprogrammed wordlines.

As further shown in FIG. 3, process 300 may include performing a second write operation to write padding data to an unprogrammed wordline of the unprogrammed wordlines that is adjacent to a last programmed wordline of the programmed wordlines (block 330). For example, the controller may perform a second write operation to write padding data to an unprogrammed wordline of the unprogrammed wordlines that is adjacent to a last programmed wordline of the programmed wordlines, as described above.

In some implementations, performing the second write operation to write the padding data to the unprogrammed wordline comprises writing, to the unprogrammed wordline, a pattern of bits that matches a pattern of bits stored by the last programmed wordline, wherein the last programmed wordline is a last wordline that is written to the first portion by the controller during the first write operation.

In some implementations, performing the second write operation to write the padding data to the unprogrammed wordline comprises writing random data to the unprogrammed wordline.

In some implementations, performing the second write operation to write the padding data to the unprogrammed wordline comprises writing predetermined data to the unprogrammed wordline.

In some implementations, performing the second write operation to write the padding data to the unprogrammed wordline comprises writing the padding data to a set of unprogrammed wordlines that includes the unprogrammed wordline and an additional unprogrammed wordline of the unprogrammed wordlines.

In some implementations, writing the padding data to the set of unprogrammed wordlines comprises writing a same pattern of bits to the unprogrammed wordline and the additional unprogrammed wordline.

In some implementations, writing the padding data to the set of unprogrammed wordlines comprises writing a first pattern of bits to the unprogrammed wordline, and writing a second pattern of bits to the additional unprogrammed wordline.

Although FIG. 3 shows example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

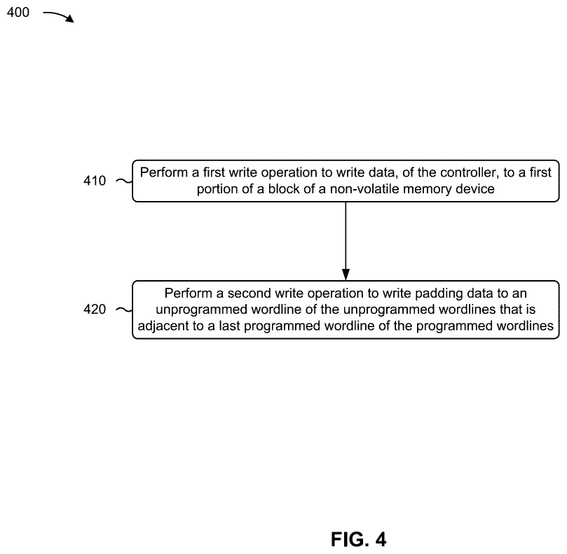

FIG. 4 is a flowchart of an example process 400 associated with improving data retention of partially programmed blocks of non-volatile memory devices field brief description of the drawings. In some implementations, one or more process blocks of FIG. 4 may be performed by a controller (e.g., controller 125). In some implementations, one or more process blocks of FIG. 3 may be performed by another device or a group of devices separate from or including the controller, such as a non-volatile memory device (e.g., non-volatile memory device 140).

As shown in FIG. 4, process 400 may include performing a first write operation to write data, of the controller, to a first portion of a block of a non-volatile memory device (block 410). For example, the controller may perform a first write operation to write data, of the controller, to a first portion of a block of a non-volatile memory device, as described above. In some implementations, the first portion of the block includes programmed wordlines. In some implementations, a second portion of the block includes unprogrammed wordlines.

As further shown in FIG. 4, process 400 may include performing a second write operation to write padding data to an unprogrammed wordline of the unprogrammed wordlines that is adjacent to a last programmed wordline of the programmed wordlines, wherein the last programmed wordline is a last wordline that is written to the first portion by the controller during the first write operation (block 420). For example, the controller may perform a second write operation to write padding data to an unprogrammed wordline of the unprogrammed wordlines that is adjacent to a last programmed wordline of the programmed wordlines, as described above. In some implementations, the last programmed wordline is a last wordline that is written to the first portion by the controller during the first write operation.

In some implementations, the padding data includes a pattern of bits that matches a pattern of bits stored by the last programmed wordline.

In some implementations, the controller is to detecting a power loss event, and performing the first write operation based on detecting the power loss event.

In some implementations, process 400 includes writing data, stored in a memory of the controller, to the first portion of the block based on detecting the power loss event.

In some implementations, process 400 includes writing random data to the unprogrammed wordline, or writing predetermined data to the unprogrammed wordline.

In some implementations, process 400 includes performing the second write operation to reduce errors associated with reading data stored by the last programmed wordline.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

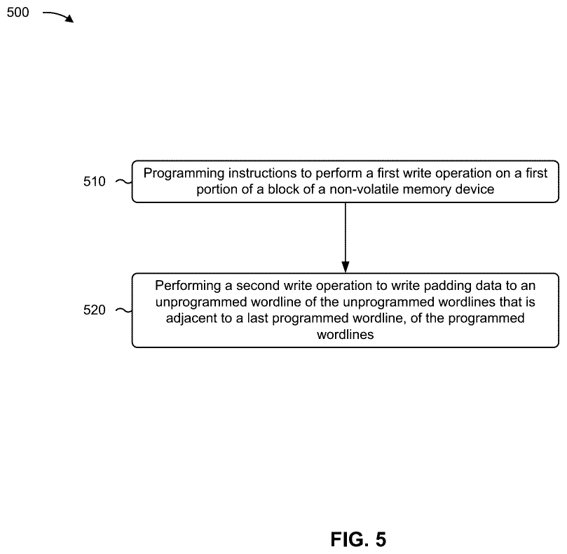

FIG. 5 is a flowchart of an example process 500 associated with improving data retention of partially programmed blocks of non-volatile memory devices field brief description of the drawings. In some implementations, one or more process blocks of FIG. 5 may be performed by a controller (e.g., controller 125). In some implementations, one or more process blocks of FIG. 5 may be performed by another device or a group of devices separate from or including the controller, such as a non-volatile memory device (e.g., non-volatile memory device 140).

As shown in FIG. 5, process 500 may include programming instructions to perform a first write operation on a first portion of a block of a non-volatile memory device (block 510). For example, the controller may program instructions to perform a first write operation on a first portion of a block of a non-volatile memory device, as described above. In some implementations, the first portion of the block includes programmed wordlines. In some implementations, a second portion of the block includes unprogrammed wordlines.

As further shown in FIG. 5, process 500 may include performing a second write operation to write padding data to an unprogrammed wordline of the unprogrammed wordlines that is adjacent to a last programmed wordline, of the programmed wordlines (block 520). For example, the controller may perform a second write operation to write padding data to an unprogrammed wordline of the unprogrammed wordlines that is adjacent to a last programmed wordline, of the programmed wordlines, as described above.

In some implementations, the program instructions to perform the second write operation comprise programming instructions to perform the second write operation to reduce errors associated with reading data stored by the last programmed wordline.

In some implementations, the program instructions to perform the second write operation comprise programming instructions to write random data to the unprogrammed wordline, or programming instructions to write predetermined data to the unprogrammed wordline.

In some implementations, the padding data includes a pattern of bits that matches a pattern of bits stored by the last programmed wordline.

In some implementations, the program instructions comprise program instructions to detect a power loss event, and programming instructions to perform the first write operation based on detecting the power loss event.

In some implementations, the program instructions to perform the first write operation comprise programming instructions to write data, stored in a memory of a controller of the non-volatile memory device, to the first portion of the block based on detecting the power loss event.

In some implementations, the program instructions to perform the second write operation comprise programming instructions to write the padding data to the unprogrammed wordline and an additional unprogrammed wordline of the unprogrammed wordlines.

Although FIG. 5 shows example blocks of process 500, in some implementations, process 500 may include additional blocks, fewer blocks, different blocks, or differently arranged blocks than those depicted in FIG. 5. Additionally, or alternatively, two or more of the blocks of process 500 may be performed in parallel.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems or methods described herein may be implemented in different forms of hardware, firmware, or a combination of hardware and software. The actual specialized control hardware or software code used to implement these systems or methods is not limiting of the implementations. Thus, the operation and behavior of the systems or methods are described herein without reference to specific software code—it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method comprising:
detecting a power loss event on a non-volatile memory device;
performing, based on detecting the power loss event, a first write operation to write data to a first portion of a block of the non-volatile memory device,
wherein, prior to the first write operation, the data is stored in a memory of a controller of the non-volatile memory device,
wherein, after the first write operation, the first portion of the block includes programmed wordlines, and
wherein, after the first write operation, a second portion of the block includes unprogrammed wordlines; and
performing a second write operation to write padding data to an unprogrammed wordline of the unprogrammed wordlines that is adjacent to a last programmed wordline of the programmed wordlines.

2. The method of claim 1, wherein performing the second write operation to write the padding data to the unprogrammed wordline comprises:
writing, to the unprogrammed wordline, a pattern of bits that matches a pattern of bits stored by the last programmed wordline,
wherein the last programmed wordline is a last wordline that is written to the first portion by the controller during the first write operation.

3. The method of claim 1, wherein performing the second write operation to write the padding data to the unprogrammed wordline comprises:
writing random data to the unprogrammed wordline.

4. The method of claim 1, wherein performing the second write operation to write the padding data to the unprogrammed wordline comprises:
writing predetermined data to the unprogrammed wordline.

5. The method of claim 1, wherein performing the second write operation to write the padding data to the unprogrammed wordline comprises:
writing the padding data to a set of unprogrammed wordlines that includes the unprogrammed wordline and an additional unprogrammed wordline of the unprogrammed wordlines.

6. The method of claim 5, wherein writing the padding data to the set of unprogrammed wordlines comprises:
writing a same pattern of bits to the unprogrammed wordline and the additional unprogrammed wordline.

7. The method of claim 5, wherein writing the padding data to the set of unprogrammed wordlines comprises:
writing a first pattern of bits to the unprogrammed wordline; and
writing a second pattern of bits to the additional unprogrammed wordline.

8. A system comprising:
a controller to:
perform a first write operation to write data, of the controller, to a first portion of a block of a non-volatile memory device,
wherein the first portion of the block includes programmed wordlines, and
wherein a second portion of the block includes unprogrammed wordlines;
and
perform a second write operation to write padding data to an unprogrammed wordline of the unprogrammed wordlines that is adjacent to a last programmed wordline of the programmed wordlines,
wherein the last programmed wordline is a last wordline that is written to the first portion by the controller during the first write operation.

9. The system of claim 8, wherein the padding data includes a pattern of bits that matches a pattern of bits stored by the last programmed wordline.

10. The system of claim 8, wherein the controller is to:
detect a power loss event; and
perform the first write operation based on detecting the power loss event.

11. The system of claim 10, wherein, to perform the first write operation, the controller is to:
write data, stored in a memory of the controller, to the first portion of the block based on detecting the power loss event.

12. The system of claim 8, wherein, to perform the second write operation, the controller is to:
write random data to the unprogrammed wordline; or
write predetermined data to the unprogrammed wordline.

13. The system of claim 8, wherein, to perform the second write operation, the controller is to:
perform the second write operation to reduce errors associated with reading data stored by the last programmed wordline.

14. A computer program product comprising:
one or more computer readable storage media, and program instructions collectively stored on the one or more computer readable storage media, the program instructions comprising:
program instructions to perform a first write operation on a first portion of a block of a non-volatile memory device,
wherein the first portion of the block includes programmed wordlines, and
wherein a second portion of the block includes unprogrammed wordlines;
and
perform a second write operation to write padding data to an unprogrammed wordline of the unprogrammed wordlines that is adjacent to a last programmed wordline, of the programmed wordlines.

15. The computer program product of claim 14, wherein the program instructions to perform the second write operation comprise:
program instructions to perform the second write operation to reduce errors associated with reading data stored by the last programmed wordline.

16. The computer program product of claim 14, wherein the program instructions to perform the second write operation comprise:
program instructions to write random data to the unprogrammed wordline; or
program instructions to write predetermined data to the unprogrammed wordline.

17. The computer program product of claim 14, wherein the padding data includes a pattern of bits that matches a pattern of bits stored by the last programmed wordline.

18. The computer program product of claim 14, wherein the program instructions comprise:
program instructions to detect a power loss event; and
program instructions to perform the first write operation based on detecting the power loss event.

19. The computer program product of claim 18, wherein the program instructions to perform the first write operation comprise:
program instructions to write data, stored in a memory of a controller of the non-volatile memory device, to the first portion of the block based on detecting the power loss event.

20. The computer program product of claim 14, wherein the program instructions to perform the second write operation comprise:
program instructions to write the padding data to the unprogrammed wordline and an additional unprogrammed wordline of the unprogrammed wordlines.
